(19) United States
(12) Patent Application Publication
(10) Pub. No.: US 2010/0129994 A1
(43) Pub. Date: May 27, 2010

(54) Method for forming a film on a substrate

(76) Inventors: Yousef Awad, Saint-Laurent (CA); Sebastien Allen, St-Lazare (CA); Michael Davies, Ottawa (CA); Alexandre Gaumond, Montreal (CA); My Ali El Khakani, St-Lambert (CA); Riadh Smirani, Montreal (CA)

Correspondence Address: FISH & RICHARDSON PC, P.O. BOX 1022, MINNEAPOLIS, MN, 55440-1022, US

(21) Appl. No.: 12/528,584

(22) PCT Filed: Feb. 27, 2008
(86) PCT No.: PCT/CA08/00357

§ 371 Date: Aug. 25, 2009

Related U.S. Application Data
(60) Provisional application No. 60/891,790, filed on Feb. 27, 2007.
(60) Provisional application No. 60/971,442, filed on Sep. 11, 2007.

(51) Int. Cl. H01L 21/365; C23C 16/44; C23C 16/50; C23C 16/48; B65D 85/00

(52) U.S. Cl. 438/483; 427/255.6; 427/578; 427/588; 427/585; 427/255.393; 427/255.394; 427/255.38; 427/255.29; 206/6; 257/E21.463

(57) ABSTRACT

A method for forming a film on a substrate comprising: heating a solid organosilane source in a heating chamber to form a gaseous precursor; transferring the gaseous precursor to a deposition chamber; and reacting the gaseous precursor using an energy source to form the film on the substrate. The film comprises Si and C, and optionally comprises other elements such as N, O, F, B, P, or a combination thereof.

### FIELD OF THE INVENTION

The present invention relates to a method for forming a silicon carbide based film on a substrate.

### BACKGROUND OF THE INVENTION

There are presently available a variety of methods and source compounds used for forming an amorphous silicon carbide based film on a substrate, some of which are discussed herein.

For example, gaseous source compounds can be used in a chemical vapor deposition (CVD) process to deposit a film on a semiconductor. Yao¹ teaches a method of producing a SiC based film requiring the use of silane and hydrocarbon gases. However, the use of an extremely pyrophoric gas such as silane gas in such a method requires costly precautionary handling procedures. The method also requires addition of hydrogen to the gaseous mixture or an elaborate means for controlling the temperature of the reactant gases due to the difference in temperature of dissociation between the silane and hydrocarbon gases.

A CVD process may be employed with a liquid polymeric source or a source compound that is dissolved or mixed into a solvent medium, such as described by Gardiner et al.² or Chayka³. However, most liquid based polymeric sources are flammable or pyrophoric, thus requiring special handling. Furthermore, Pitcher et al.⁴ teach that a treatment time in excess of 48 hours and a pyrolysis time in excess of 24 hours are required.

Starfire Systems⁵ has developed a method of producing stoichiometric SiC films from stoichiometric source compounds. In this method, the two sources (CVD-2000™ and CVD-4000™) are liquid, flammable (flash point 9° C., 51° C.), and air and moisture sensitive.

Goela et al.⁶ teach a CVD process using a chlorine-containing source compound either in a gas or liquid form. However, the chlorine containing source compound forms corrosive and toxic hydrogen chloride fumes upon contact with moisture, which significantly complicates storage, disposal, handling, and pumping of such material.

Spin coating methods have been used wherein a polymeric source is dissolved in a solvent and then applied to a substrate by spinning, dipping, spraying, swabbing, or brushing. Subsequently, pyrolysis of the source on the substrate occurs at an elevated temperature, for example 1000° C. or more for several hours (see Moehle et al.⁷). In addition to limitations of substrate shape and orientation in the spin coating method, the high temperature of pyrolysis limits the type of material used as the substrate. The method also results in a high density of defects (voids) due to outgassing of solvent during pyrolysis, uneven film thickness due to the spin coating, and cracks due to shrinkage of the films.

Ruppel et al.⁸ teaches a method of coating a substrate by sputtering, which produces a non-stoichiometric film. A good deal of heat is generated as the sputtering rate increases, which may destroy the substrate, for example when the substrate is made from plastic. Further, film produced by sputtering is usually hydrogen free, which is a major disadvantage for semiconductor applications.

Silicon carbide based films such as those described above have been used for reduction of the surface recombination velocity, also described as surface passivation, of silicon semiconductor samples such as silicon wafer based solar cells. Films having better passivation characteristics would increase the efficiency of these devices. However, due to the high cost and toxicity of gases that are often involved in making these devices, production of such passivation layers for devices may not always be viable.

### SUMMARY OF THE INVENTION

According to one aspect of the present invention, there is provided a method for forming a film on a substrate comprising: heating a solid organosilane source in a heating chamber to form volatile fragments of the solid organosilane source (also referred to herein as the gaseous precursor); transferring the gaseous precursor to a deposition chamber containing the substrate; and reacting the gaseous precursor using an energy source to form a film on the substrate. In an embodiment, the energy source is plasma. In another embodiment, the transferring step may comprise using a carrier gas. In yet another embodiment, the method may further comprise mixing the gaseous precursor with a reactant gas prior to the reacting step; the gaseous precursor and the reactant gas may be admixed prior to transfer to the deposition chamber, or the gaseous precursor and reactant gas can both be transferred separately to the deposition chamber. In still another embodiment, the deposition chamber is within a reactor and the heating chamber is external to the reactor. In yet another embodiment, the deposition chamber and the heating chamber are both within a reactor.

According to another aspect of the present invention, there is provided a method for surface passivation of a silicon based semiconductor, comprising depositing a film on the surface of the semiconductor according to the method described herein, the semiconductor and deposited film being optionally annealed.

According to still another aspect of the present invention, there is provided a container comprising a gaseous precursor produced by heating a solid organosilane source for use in a method for forming a film on a substrate.

### BRIEF DESCRIPTION OF THE DRAWINGS

In the accompanying drawings, which illustrate an exemplary embodiment of the present invention:

FIG. 1 is a graph from Elastic Recoil Detection (ERD) of a a-SiCN:H sample;

FIG. 2 is a graph from Elastic Recoil Detection (ERD) of a a-SiCN:H sample;

FIG. 3 is a graph from Elastic Recoil Detection (ERD) of a a-SiCN:H sample;

FIG. 4 is the output from the measurement of lifetime using the μ-PCD technique;

FIG. 5(a) is the output from the effective lifetime measurement of a FZ Si wafer passivated by a-SiCN:H using the Sinton technique;

FIG. 5(b) is a graph showing the implied open circuit voltage of a Si substrate as a function of light intensity;

FIG. 6 is a graph of effective lifetime of an a-SiCN:H coated FZ Si wafer as a function of film thickness;

FIG. 7 is graph of effective lifetime of the a-SiCN:H films as a function of silicon to nitrogen ratio;

FIG. 8 is an optical transmission spectrum of the a-SiCN:H films deposited on quartz at 400*C using, PDMS single source and NH₃ added to the gas flow. Four different samples were prepared to confirm the process repeatability. The thickness of the a-SiCN:H films is typically 80±5 nm;

FIG. 9 is a graph of absorption coefficient and wavelength for films prepared by the method described herein and prior art films; and

FIG. 10 is a schematic of a solar cell with multiple optical coatings on each major surface, each having a refractive index n¹, n², n^{x}, n^{′1}, n^{′2} or n^{′y}.

### DETAILED DESCRIPTION OF THE INVENTION

The present invention relates to a method for forming a film on a substrate comprising heating a solid organosilane source in a heating chamber to form a gaseous precursor, transferring the gaseous precursor to a deposition chamber, and reacting the gaseous precursor using an energy source to form the film on the substrate.

The method of the present invention may produce near-stoichiometric SiC films on a substrate even when the Si:C ratio in the solid organosilane source is non-stoichiometric. If the solid organosilane is PDMS, the method may require less silicon-carbon bond formation on the surface of the substrate, since Si—C bonds in the pre-cursor gas can be obtained during the Kumada re-arrangement preceding the deposition of the film. For other organosilane solids (e.g. polycarbosilane), the method may require less silicon-carbon bond formation on the surface of the substrate, since Si—C bonds can be provided in the gaseous precursor obtained from the organosilane solid, which is volatised preceding the deposition of the film. Further, the method does not require any solvents thereby eliminating cracking, shrinking, voids or porosity formation due to outgassing of solvents.

### Solid Organosilane Source

A solid organosilane source refers to compounds that comprise Si, C and H atoms, and that are solid at room temperature and pressure.

The solid organosilane source may, in one embodiment, be a silicon-based polymer comprising Si—C bonds that are thermodynamically stable during heating in the heating chamber. In one embodiment, the silicon-based polymer has a monomeric unit comprising at least one silicon atom and two or more carbon atoms. The monomeric unit may further comprise additional elements such as N, O, F, B, P, or a combination thereof. In another embodiment, the polymeric source is a polysilane or a polycarbosilane.

The polysilane compound can be any solid polysilane compound that can produce gaseous organosilicon compounds when pyrolysed, i.e. chemical decomposition of the solid polysilane by heating in an atmosphere that is substantially free of molecular oxygen. In one embodiment, the solid polysilane compound comprises a linear or branched polysilicon chain wherein each silicon is substituted by one or more hydrogen atoms, C₁-C₆ alkyl groups, phenyl groups or —NH₃ groups. In a further embodiment, the linear or branched polysilicon chain has at least one monomeric unit comprising at least one silicon atom and one or more carbon atoms. In another embodiment, the linear or branched polysilicon chain has at least one monomeric unit comprising at least one silicon atom and two or more carbon atoms.

Examples of solid organosilane sources include silicon-based polymers such as polydimethylsilane (PDMS) and polycarbomethylsilane (PCMS), and other non-polymeric species such as triphenylsilane or nonamethyltrisilazane. PCMS is commercially available (Sigma-Aldrich) and can have, for example, an average molecular weight from about 800 g/mol to about 2000 g/mol. PDMS is also commercially available (Gelest, Morrisville, Pa. and Stem Chemical, Inc., Newburyport, Mass.) and it can have, for example, an average molecular weight from about 1100 to about 1700. PDMS is known as a polymer able to yield polycarbosilane. Use of PDMS as a source compound is advantageous in that (a) it is very safe to handle with regard to storage and transfer, (b) it is air and moisture stable, a desirable characteristic when using large volumes in industrial environment, (c) no corrosive components are generated in an effluent stream resulting from PDMS being exposed to CVD process conditions, and (d) PDMS provides its own hydrogen supply by virtue of its hydrogen substituents and yields dense amorphous SiC at temperatures as low as 50° C.

In another embodiment, the solid organosilane source may have at least one label component, the type, proportion and concentration of which can be used to create a chemical “fingerprint” in the obtained film that can be readily measured by standard laboratory analytical tools, e.g. Secondary Ion Mass Spectrometry (SIMS), Auger Electron Spectrometry (AES), X-ray photoelectron spectroscopy (XPS).

In one embodiment, the solid organosilane source can contain an isotope label, i.e. a non-naturally abundant relative amount of at least one isotope of an atomic species contained in the solid organosilane source, e.g. C¹³ or C¹⁴. This is referred to herein as a synthetic ratio of isotopes.

### Formation of the Gaseous Precursor Species

In one embodiment, the solid organosilane source may be added to the heating chamber in a batch or continuous manner as a powder, pellet, rod or other solid form. Optionally, the solid organosilane source may be mixed with a second solid polymer in the heating chamber. In batch addition, the solid organosilane source compound may be added, for example, in an amount in the range of from 1 mg to 10 kg, although larger amounts may also be used.

In one embodiment the heating chamber is purged, optionally under vacuum, after the solid organosilane source has been added to replace the gases within the chamber with an inert gas, such as argon or helium. The chamber can be purged before heating is commenced, or the temperature within the chamber can be increased during, or prior to, the purge. The temperature within the chamber during the purge should be kept below the temperature at which evolution of the gaseous precursor species commences to minimise losses of product.

The production of the gaseous precursor from the solid organosilane source is achieved through a pyrolysis step, which can encompass one or more different types of reactions within the solid. The different types of reactions, which can include e.g. volatisation of the solid organosilane source or decomposition/rearrangement of the solid organosilane into a new gaseous organosilane species, will depend on the nature of the solid organosilane source, and these reactions can also be promoted by the temperature selected for the pyrolysis step. For embodiments where the solid organosilane source is a polysilane, the gaseous precursor species can be obtained through a process as described in U.S. provisional application Ser. No. 60/990,447 filed on Nov. 27, 2007, the disclosure of which is incorporated herein by reference in its entirety.

The heating of the solid organosilane source in the heating chamber may be performed by electrical heating, UV irradiation, IR irradiation, microwave irradiation, X-ray irradiation, electronic beams, laser beams or the like.

The heating chamber is heated to a temperature in the range of, for example, from about 50 to about 700° C., from about 100 to about 700° C., from about 150 to about 700° C., from about 200 to about 700° C., from about 250 to about 700° C., from about 300 to about 700° C., from about 350 to about 700° C., from about 400 to about 700° C., from about 450 to about 700° C., from about 500 to about 700° C., from about 550 to about 700° C., about 600 to about 700° C., from about 650 to about 700° C., from about 50 to about 650° C., from about 50 to about 600° C., from about 50 to about 550° C., from about 50 to about 500° C., from about 50 to about 450° C., from about 50 to about 400° C., from about 50 to about 350° C., from about 50 to about 300° C., from about 50 to about 250° C., from about 50 to about 200° C., from about 50 to about 150° C., from about 50 to about 100° C., from about 100 to about 650° C., from about 150 to about 600° C., from about 200 to about 550° C., from about 250 to about 500° C., from about 300 to about 450° C., from about 350 to about 400° C., from about 475 to about 500° C., about 50° C., about 100° C., about 150° C., about 200° C., about 250° C., about 300° C., about 350° C., about 400° C., about 450° C., about 500° C., about 550° C., about 600° C., about 650° C., or about 700° C. A higher temperature can increase the rate at which the gaseous precursor compounds are produced from the solid organosilane source.

In one embodiment, the heating chamber is heated at a rate of up to 150° C. per hour until the desired temperature is reached, at which temperature the chamber is maintained. In another embodiment, the temperature is increase to a first value at which pyrolysis proceeds, and then the temperature is changed on one or more occasion, e.g.: in order to vary the rate at which the mixture of gaseous precursor compound is produced or to vary the pressure within the chamber.

In one embodiment the temperature and pressure within the heating chamber are controlled, and production of the gaseous precursor can be driven by reducing the pressure, by heating the organosilane source, or by a combination thereof. Selection of specific temperature and pressure values for the heating chamber can also be used to control the nature of the gaseous precursor obtained.

In the embodiment where the solid organosilane source is a polysilane, one possible pyrolisis reaction leads to the formation of Si—Si crosslinks within the solid polysilane, which reaction usually takes place up to about 375° C. Another possible reaction is referred to as the Kumada rearrangement, which typically occurs at temperatures between about 225° C. to about 350° C., wherein the Si—Si backbone chain becomes a Si—C—Si backbone chain. While this type of reaction is usually used to produce a non-volatile product, the Kumada re-arrangement can produce volatile polycarbosilane oligomers, silanes and/or methyl silanes. While the amount of gaseous species produced by way of the Kumada rearrangement competes with the production of non-volatile solid or liquid polycarbosilane, the production of such species, while detrimental to the overall yield, can prove a useful aspect of the gas evolution process in that any material, liquid or solid that is left in the heating chamber is in some embodiments turned into a harmless and safe ceramic material, leading to safer handling of the material once the process is terminated.

For the embodiment where the solid organosilane is a polysilane, the pressure within the heating chamber can be maintained at a predetermined pressure or within a predetermined pressure range in order to provide a desired molar ratio of gaseous precursor compounds in the produced gaseous mixture. Generally, maintaining a high pressure, e.g. 600 to 900 psi, favours the production of gaseous precursor species having a lower molecular weight (e.g. a lower number of silicon atoms), while maintaining a lower pressure, e.g. 100 to 250 psi, favours the production of gaseous organosilicon species having a higher molecular weight (e.g. higher number of silicon atoms).

### Gaseous Precursor Species

Generally, the gaseous precursor comprises a mixture of volatile fragments of the solid organosilane source. In the embodiment where the solid organosilane precursor is a polysilane, the gaseous precursor species is a mixture of gaseous organosilicon compounds, i.e. compounds comprising silicon, carbon and hydrogen atoms that are in the gas phase at 20° C. and 20 psi.

In one embodiment, the mixture of gaseous organosilicon compounds comprises one of more gases selected from a gaseous silane, a gaseous polysilane, or a gaseous polycarbosilane. In another embodiment, substantially all of the gaseous organosilicon compounds produced within the mixture comprise from 1 to 4 silicon atoms. By gaseous silane is meant a compound comprising a single silicon atom, by gaseous polysilane is meant a compound comprising two or more silicon atoms wherein the silicon atoms are covalently linked (e.g. Si—Si), and by gaseous polycarbosilane is meant a compound comprising two or more silicon atoms wherein at least two of the silicon atoms are linked through a non-silicon atom (e.g. Si—CH₂—Si).

In a further embodiment, the gaseous organosilicon compound can be a gaseous polycarbosilane of formula:

Si(CH₃)ₙ(H)ₘ—[(CH₂)—Si(CH₃)ₚ(H)_{q}]ₓ—Si(CH₃)_{n′}(H)_{m′}

wherein n, m, n′ and m′ independently represent an integer from 0 to 3, with the proviso that n+m=3 and n′+m′=3, p and q independently represent an integer from 0 to 2, with the proviso that p+q=2 for each silicon atom, and x is an integer from 0 to 3.

Examples of gaseous silanes and gaseous polycarbosilanes include silane, dimethyl, trimethyl silane, tetramethyl silane, [Si(CH₃)(H)₂]—CH₂—[Si(CH₃)₂(H)], [Si(CH₃)₂(H)]—CH₂—[Si(CH₃)₂(H)], [Si(CH₃)₃]—CH₂—[Si(CH₃)₂(H)], [Si(CH₃)₂(H)]—CH₂—[Si(CH₃)₂]—CH₂—[Si(CH₃)₃], [Si(CH₃)(H)₂]—CH₂—[Si(CH₃)₂]—CH₂—[Si(CH₃)(H)₂], [Si(CH₃)(H)₂]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)(H)₂], and [Si (H)₃]—CH₂—[Si(CH₃)₂]—CH₂—[Si(CH₃)₂]—CH₂—[Si(CH₃)(H)₂].

After forming the gaseous precursor, it may be used immediately or stored under appropriate temperature and pressure conditions for later use. The process may be interrupted at this stage since the heating chamber may be external to the reactor.

### Addition of a Reactant Gas

After heating, the gaseous precursor formed may be mixed with a reactant gas in the heating chamber, the deposition chamber or in a gas mixing unit. In one embodiment, the reactant gas may be in the form of a gas that is commercially available, and the gas is provided directly to the system. In another embodiment, the reactant gas is produced by heating a solid or liquid source comprising any number of elements, such as N, O, F, B, P, or a combination thereof.

For example, the reactant gas may be produced by heating a solid source comprising phosphorous such as triphenylphosphine (C₆H₅)₃P; a solid source comprising nitrogen such as tris(pyrazol-1-yl)methane); or a solid source comprising boron such as borane t-butylamine (CH₃)₃CNH₂:BH₃, triethanolamineborate B (OCH₂CH₂)₃N, borane dimethylamine (CH₃)₂NH:BH₃, or triphenylboron B(C₆H₅)₃. Aida et al.⁹ reported the use of triphenylphosphine (C₆H₅)₃P as a good source of phosphine for doping a-SiC prepared by RF sputtering of Si target in the presence of a (C₆H₅)₃P disk.

In another example, the reactant gas may be produced by heating a liquid source comprising fluorine such as difluorobenzene (C₆H₄F₂); a liquid source comprising phosphorous such as triethylphosphine (C₂H₅)₃P, dimethylphenylphosphine (CH₃)₂(C₆H₅)P, or tris(trimethylsilyl)phosphine [(CH₃)₃Si]₃P; or a liquid source comprising boron such as tris(trimethylsiloxy)boron [(CH₃)₃SiO]₃B. Riedel et al.¹⁰ reported doping a SiCN ceramic using polymeric source tris[[dichloromethylsilyl]ethyl]boron) and Ramakrishnan et al.¹¹ reported using polyhydridomethlsilazane (NCP 200™) and tris[[dichloromethylsilyl]ethyl]borane polymer precursors as p-type dopant for SiCN ceramics.

In still another example, the reactant gas may be a nitrogen based gas such as NH₃, N₂, or NCl₃; an oxygen based gas such as CO, O₂, O₃, CO₂; a fluorine based gas such as CF₄, C₄F₈, CH₂F₂, NF₃, C₂F₆, C₃F₈, CHF₃, C₂F₄, C₃F₆, or a combination thereof; a boron based gas such as BH₃, B₂H₆, BCl₃, B₂Cl₆; or a phosphorous based gas such as PH₃ or PCl₃.

In an embodiment, the reactant gas may also comprise Al, B, Ge, Ga, P, As, N, In, Sb, S, Se, Te, In and Sb.

### Configuration of Heating and Deposition Chambers

The method of the present invention may be carried with a variety of system configurations, such as a heating chamber and a deposition chamber; a heating chamber, a gas mixing unit and a deposition chamber; a heating chamber, a gas mixing unit and a plurality of deposition chambers; or a plurality of heating chambers, a gas mixing unit and at least one deposition chamber. In a preferred embodiment, the deposition chamber is within a reactor and the heating chamber is external to the reactor.

For high throughput configurations, multiple units of the heating chamber may be integrated. Each heating chamber in the multiple-unit configuration may be of a relatively small scale in size, so that the mechanical construction is simple and reliable. All heating chambers may supply common gas delivery, exhaust and control systems so that cost is similar to a larger conventional reactor with the same throughput. In theory, there is no limit to the number of reactors that may be integrated into one system.

The method of the present invention may also utilize a regular mass flow or pressure controller to more accurately deliver appropriate process demanded flow rates. The gaseous precursor may be transferred to the deposition chamber in a continuous flow or in a pulsed flow.

The method of the present invention may in some embodiments utilize regular tubing without the need of special heating of the tubing as is the case in many liquid source CVD processes in which heating the tubing lines is essential to eliminate source vapor condensation, or earlier decomposition of the source.

### Deposition Chamber

When it is desired to form a film, the substrate is placed into the deposition chamber, which is evacuated to a sufficiently low pressure, and the gaseous precursor and optionally the reactant and carrier gas are introduced continuously or pulsed. Any pressure can be selected as long as the energy source selected to effect the deposition can be used at the selected pressure. For example, when plasma is used as the energy source, any pressure under which a plasma can be formed is suitable. In embodiments of the present invention the pressure can be from about 50 to about 500 mTorr, from about 100 to about 500 mTorr, from about 150 to about 500 mTorr, from about 200 to about 500 mTorr, from about 200 to about 500 mTorr, from about 250 to about 500 mTorr, from about 300 to about 500 mTorr, from about 350 to about 500 mTorr, from about 400 to about 500 mTorr, from about 450 to about 500 mTorr, from about 50 to about 450 mTorr, from about 50 to about 400 mTorr, from about 50 to about 350 mTorr, from about 50 to about 300 mTorr, from about 50 to about 250 mTorr, from about 50 to about 200 mTorr, from about 50 to about 150 mTorr, from about 50 to about 100 mTorr, from about 100 to about 450 mTorr, from about 150 to about 400 mTorr, from about 200 to about 350 mTorr, from about 250 to about 300 mTorr, from about 50 mTorr to about 5 Torr, from about 50 mTorr to about 4 Torr, from about 50 mTorr to about 3 Torr, from about 50 mTorr to about 2 Torr, from about 50 mTorr to about 1 Torr, about 50 mTorr, about 100 mTorr, about 150 mTorr, about 200 mTorr, about 250 mTorr, about 300 mTorr, about 350 mTorr, about 400 mTorr, about 450 mTorr, about 500 mTorr, about 1 Torr, about 2 Torr, about 3 Torr, about 4 Torr, or about 5 Torr.

The substrate is held at a temperature in the range of, for example, from about 25 to about 500° C., from about 50 to about 500° C., from about 100 to about 500° C., from about 150 to about 500° C., from about 200 to about 500° C., from about 250 to about 500° C., from about 300 to about 500° C., from about 350 to about 500° C., from about 400 to about 500° C., from about 450 to about 500° C., from about 25 to about 450° C., from about 25 to about 400° C., from about 25 to about 350° C., from about 25 to about 300° C., from about 25 to about 250° C., from about 25 to about 200° C., from about 25 to about 150° C., from about 25 to about 100° C., from about 25 to about 50° C., from about 50 to about 450° C., from about 100 to about 400° C., from about 150 to about 350° C., from about 200 to about 300° C., about 25° C., about 50° C., about 100° C., about 150° C., about 200° C., about 250° C., about 300° C., about 350° C., about 400° C., about 450° C., or about 500° C.

Any system for conducting energy induced chemical vapor deposition (CVD) may be used for the method of the present invention. Other suitable equipment will be recognized by those skilled in the art. The typical equipment, gas flow requirements and other deposition settings for a variety of PECVD deposition tools used for commercial coating solar cells can be found in True Blue, Photon International, March 2006 pages 90-99 inclusive, the contents of which are enclosed herewith by reference.

The energy source in the deposition chamber may be, for example, electrical heating, hot filament processes, UV irradiation, IR irradiation, microwave irradiation, X-ray irradiation, electronic beams, laser beams, plasma, or RF. In a preferred embodiment, the energy source is plasma.

For example, suitable plasma deposition techniques may be plasma enhanced chemical vapor deposition (PECVD), radio frequency plasma enhanced chemical vapor deposition (RF-PECVD), electron-cyclotron-resonance plasma-enhanced chemical-vapor deposition (ECR-PECVD), inductively coupled plasma-enhanced chemical-vapor deposition (ICP-ECVD), plasma beam source plasma enhanced chemical vapor deposition (PBS-PECVD), or combinations thereof. Furthermore, other types of deposition techniques suitable for use in manufacturing integrated circuits or semiconductor-based devices may also be used.

### Substrate

A wide variety of substrate materials may be used since the formation of the film on the substrate occurs at a relatively low temperature. Suitable materials for the substrate may be, for example, metallic and inorganic materials, elementary silicon, carbon and ceramic materials such as silicon carbide, silicon nitride, alumina, quartz, glass or plastic, as well as heat-resistance synthetic resins such as fluorocarbon polymers or polyamide resins. In an embodiment, the substrate is a FZ Si(100) wafer.

The film of the present invention is particularly applicable to solar cells fabricated from silicon. In this context the film can be applied to amorphous, crystalline, or polycrystalline silicon as well as n-doped, p-doped, or intrinsic silicon. When used as an antireflective coating, the film can be applied to the external n-doped and/or p-doped surfaces of a solar cell to optimally minimise reflections from these surfaces and to reduce the absorption 0 of the light in the film to below 1%.

### Films

The film formed on the substrate may have the chemical formula SiₓC_{y} wherein x and y may be, for example, from about 0.2 to about 0.8, from about 0.3 to about 0.8, from about 0.4 to about 0.8, from about 0.5 to about 0.8, from about 0.6 to about 0.8, from about 7 to about 0.8, from about 0.2 to about 0.7, from about 0.2 to about 0.6, from about 0.2 to about 0.5, from about 0.2 to about 0.4, from about 0.2 to about 0.3, from about 0.3 to about 0.7, from about 0.4 to about 0.6, about 0.2, about 0.3, about 0.4, about 0.5, about 0.6, about 0.7, or about 0.8. In a preferred embodiment, x and y is about 0.5. The film may further comprise other elements such as N, O, F, B, P, or a combination thereof.

In an embodiment, the film may be a silicon carbide (SiC), a silicon carbofluoride (SiCF), a silicon carbonitride (SiCN), a silicon oxycarbide (SiOC), a silicon oxycarbonitride (SiOCN), a silicon carboboride (SiCB), a silicon carbonitroboride (SiCNB), a silicon carbophosphide (SiCP), or a combination thereof. The film may be multilayered or it may have a gradient of composition, e.g. a silicon oxycarbonitride film where the oxygen concentration varies at different thicknesses within the film.

For embodiments where the energy used during the deposition is plasma, e.g. for PE-CVD, the values of x and y may be controlled by suitably selecting conditions for (1) the generation of the plasma, (2) the temperature of the substrate, (3) the power and frequency of the reactor, (4) the type and amount of gaseous precursor introduced into the deposition chamber, and (5) the mixing ratio of gaseous precursor and reactant gas.

For example, the silicon:carbon ratio of the silicon carbide layer is tunable in that it may be varied as a function of the RF power. The silicon:carbon ratio may be in a range of about 1:2 to about 2:1. For example, the silicon:carbon ratio in a silicon carbide layer formed at RF power of 900 W is about 0.94:1, while silicon:carbon ratio of a silicon carbide layer formed at RF power of 400 W is 1.3:1. A stoichiometric silicon carbide layer may be formed at RF power of about 700 W.

The silicon:carbon ratio may also be varied as a function of substrate temperature. More particularly, as the substrate temperature is increased, the silicon:carbon ratio in the deposited silicon carbide layer decreases.

The silicon:carbon ratio is also tunable as a function of the composition of the gas mixture during SiC layer formation.

The films produced by the method described herein have improved properties, such as excellent passivation, low mechanical stress, low absorption coefficient of light and a controllable refractive index.

These improved properties can be used to minimize some of the limitations which negatively affect solar cell efficiency, which limitations include front surface reflection; optical losses, e.g. those due to randomly textured surface, especially in the shorter wavelength region; and internal parasitic losses, such as those due to random texture, SiO₂ AR, metallization design and absorption of light in the metal contact.

These films my also be used as optical coatings, e.g. as anti-scratch and/or anti-reflective coatings.

### Passivation

The invention also relates to the passivation of surfaces of semiconductors using the films prepared by the method described herein. These films can be used to passivate both N and P type material.

The films can be used as a passivating layer to reduce surface generation and recombination effects at insulator-semiconductor interfaces. Application of these films can also increase the bulk lifetime of a semiconductor substrate. Such an increase is more pronounced for semiconductor material having a low bulk lifetime, e.g. a bulk lifetime of less than 100 μs. The reason for the bulk lifetime increase may be due to the amount of hydrogen present during the deposition (from the gaseous precursor and optional reactant gases), which hydrogen may diffuse into the bulk of the semiconductor to passivate bulk defects, thus improving the bulk lifetime. It is also advantageous to have films containing significant amounts of hydrogen to act as sources of dangling bond passivation during post deposition processing, such as annealing.

While films known in the art can produce good passivation results, the films produced by the technique described herein provide unexpectedly high passivation results. While a precursor with a high C:Si content would be expected to lead to a film having a large number of C—C or C═C bonds in the film (which bonds are known to deteriorate passivation performance), the present methods provide high C:Si content while promoting the presence of C—Si bonds in the obtained film.

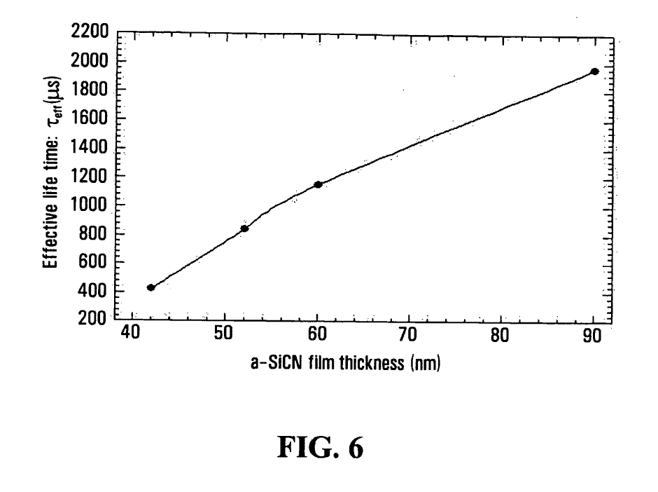

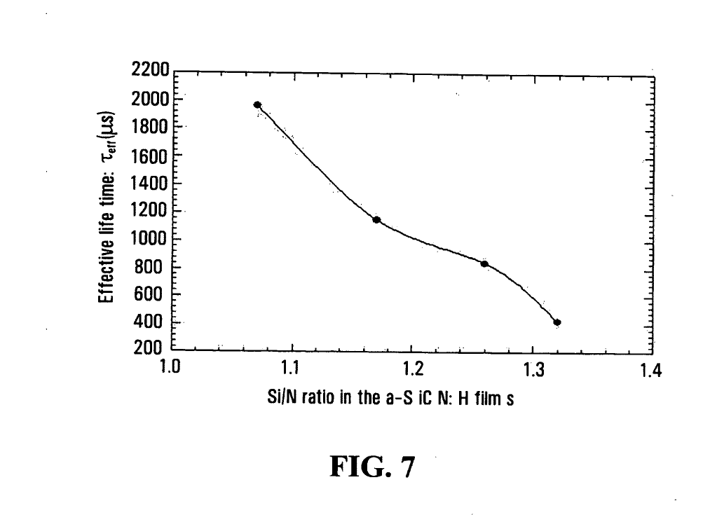

The minority effective lifetime with respect to film thickness and Si/N ratio are illustrated in FIGS. 6 and 7, respectively.

Multilayer structures produced by the method described herein may also replace the complex step of texturing the front surface of solar cells to diffuse-incoming light. Texturing of the front of solar cells may lead to the formation of physical defects, which defects promote recombination effects at the semiconductor surface. Presence of a passivating layer in combination with the abstraction of the texturing defects leads to better passivation performance of the obtained substrate.

The passivating layer can optionally be annealed in order to ameliorate its interface with the top and/or bottom side of a semiconductor device, to reduce the density of crystallographic defects, to reduce the density of trap states, or to attain other well-known benefits of thermal annealing. Annealing is most commonly accomplished by means of rapid thermal annealing (RTA), hot-gas annealing, belt furnace annealing or isothermal annealing, though many other annealing techniques are suitable and well-known. Annealing can be carried out during and/or after deposition of the passivating films.

### Low Absorption Coefficient of Light

High light absorption of passivating thin films produces a loss in the short-circuit current, which can in turn reduce the efficiency of a solar cell. Passivating thin films having low absorption are expected to increase efficiency of solar cells. Furthermore, the absorption, especially in the UV range, results in fast heating of the solar cell due to the high energy of the UV light. Such heating can reduce the lifetime of the solar cell. Further, absorption of UV light can lead to degradation of the cell.

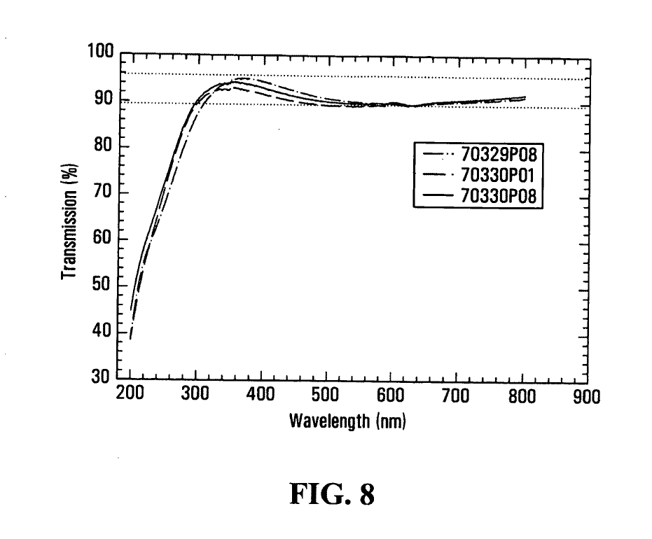

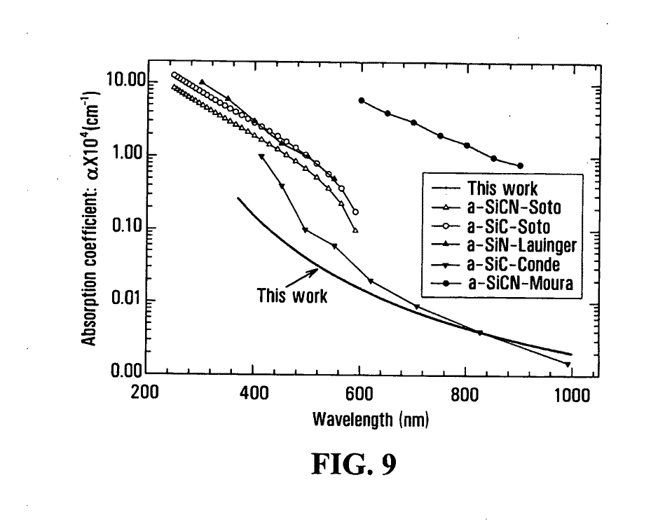

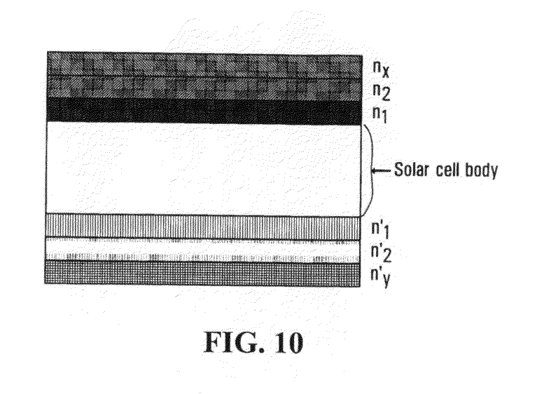

The transmission of light in the visible spectra of the exemplary films is shown in FIG. 8. The a-SiCN:H film produced by the method described herein shows a decrease in the absorption coefficient of light by 1-2 orders of magnitude compared to many SiC, SiN and SiCN films (FIG. 9).

### Controllable Refractive Index

Using the methods described herein, it is possible to control the concentration of the elements in the passivating film deposited on the semiconductor surface, thus controlling the refractive index of the film. For example, by minimizing the concentration of carbon in the film and by maximizing the concentration of nitrogen, oxygen, or both, a film having a refractive index similar to that of silicon nitride, silicon oxide or silicon oxynitride, can be prepared to provide a broad range of achievable refractive indexes for the prepared films. For example, it is feasible to introduce O or N into a PDMS flow stream in a single deposition by which the refractive index can be tailored from 1.5-2.3. Such a control can prove beneficial, as the control of the refractive index can dictate the reflectivity of the film.

Variations in reflection (increase and decrease) can be achieved by the addition of one or more film layers having a constant refractive index, or by the addition of a single film layer having a gradient in refractive index.

Deposition of a multilayer structure by the methods described herein may be optimized with regard to passivation and anti-reflection properties by variation of the deposition process parameters and thickness of each layer.

A gradient film layer, i.e. a layer having a graded refractive index, can also be prepared using the method described herein. For example, increasing the concentration of a reactant gas comprising oxygen or nitrogen into the deposition chamber may lead to an increase in the concentration of that atom in the layer. Since such a concentration can be continually adjusted during a single deposition, the refractive index of the layer can be varied through its thickness.

For example, a front anti-reflection material can be prepared by way of a multilayer film of silicon carbide with varying concentrations of oxygen and nitrogen (e.g. silicon carbonitride, silicon oxycarbide and silicon oxycarbonitride).

The gradient or multilayer films can also be utilized to increase reflection for the backside of a solar cell while increasing surface passivation. Current manufacturing solutions for solar cells have the rear metal contact directly against the silicon, with no backside coatings. While presence of the metal does have a surface passivating effect, a passivation layer as described herein may be added to the backside of the cell to improve performance.

Further, application of a gradient or multi-layer coating to the back of the solar cell can also be used to optimize back reflection of incident light, permitting the light to twice cross the absorption junction. The back reflective mirror may be achieved by applying a graded refractive index film or multiple film layers on the back of the solar cell, where the lower refractive index is closer to the cell, and the higher refractive index is further from the cell.

### EXAMPLES

The following examples are provided to illustrate the invention. It will be understood, however, that the specific details given in each example have been selected for the purpose of illustration and are not to be construed as limiting the scope of the invention.

The PECVD tool used to deposit the films in the following examples was manufactured by Applied Materials (Plasma II model). This PECVD tool has a parallel plate geometry. The plasma is generated by applying power from a 40 KHz Advanced Energy PE-2500 power supply across the system electrodes. The substrate electrode temperature can be controlled from room temperature to 450 C, the operating pressure can be varied from ˜200 milli-Torr to 3 Torr by controlling gas flows and/or pumping speed.

### Example 1

### Stoichiometric a-SiC (source is PDMS)

A 4″ diameter single-crystalline semiconductor silicon wafer was placed on a grounded electrode in a PECVD system and heated at 300° C. by energizing a heater built into the electrode. The deposition chamber was then evacuated by operating a vacuum pump. When the pressure inside the deposition chamber had reached 0.05 Torr, vapor of PDMS was introduced thereinto at such a rate that the pressure inside the deposition chamber was kept at 0.215 Torr by the balance of the continuous introduction of the vapor and evacuation. A high frequency electric power of 600 watts at a frequency of 40 KHz was supplied between the electrodes for 4 minutes to generate plasma inside the deposition chamber to which the silicon wafer on the electrode was exposed.

After removal from the deposition chamber, the silicon wafer was found to be coated with an amorphous silicon carbide film having the formula Si_{0.5}C_{0.5} in a nearly pure state. The film had a thickness of 0.1 μm.

### Example 2

### a-SiC on plastic (source is PDMS)

A 5 cm×5 cm plastic plate was placed on a grounded electrode of an apparatus without heating. The deposition chamber was evacuated by operating a vacuum pump. When the pressure inside the deposition chamber had reached 0.05 Torr, vapor of PDMS was introduced thereinto at such a rate that the pressure inside the deposition chamber was kept at 0.40 Torr by the balance of the continuous introduction of the vapor and evacuation. A high frequency electric power of 750 watts at a frequency of 40 KHz was supplied between the electrodes for 20 minutes to generate plasma inside the deposition chamber to which the plastic plate on the electrode was exposed. The temperature of the substrate rose to 75° C. due to plasma heating.

After removal from the deposition chamber, the plastic plate was found to be coated with a light yellow amorphous silicon carbide film having the formula Si_{0.5}C_{0.5} in a nearly pure state. The film had a thickness of 0.2 μm.

### Example 3

### a-SiCN (source is PDMS+N₂)

The method was carried out as described in Example 1 with 500 sccm N₂ gas added to the stream of the PDMS vapor. The total flow of PDMS and N₂ was adjusted to keep a pressure of 0.38 Torr inside the deposition chamber. The duration of deposition was 15 minutes and the temperature of the substrate was 300° C.

After removal from the deposition chamber, the silicon wafer was found to be coated with an amorphous silicon carbonitride film having the formula Si_{0.4}C_{0.3}N_{0.3} in a nearly pure state. The film had a thickness of 0.280 μm.

### Example 4

### a-SiCN (source is PDMS+NH₃)

The method was carried out as described in Example 1 with 500 sccm NH₃ gas added to the stream of the PDMS vapor. The total flow of PDMS and NH₃ was adjusted to keep a pressure of 0.38 Torr inside the deposition chamber. The duration of deposition was 30 minutes and the temperature of the substrate was 300° C.

After removal from the deposition chamber, the silicon wafer was found to be coated with an amorphous silicon carbonitride film having the formula Si_{0.4}C_{0.15}N_{0.45} in a nearly pure state. The film had a thickness of 0.300 μm.

### Example 5

### a-SiCF (source is PDMS+CF₄)

The method was carried out as described in Example 1 with 100 sccm CF₄ gas added to the stream of the PDMS vapor. The total flow of PDMS and CF₄ was adjusted to keep a pressure of 0.44 Torr inside the deposition chamber. The duration of deposition was 10 minutes and the temperature of the substrate was 300° C.

After removal from the deposition chamber, the silicon wafer was found to be coated with an amorphous silicon carbofluoride film having the formula Si_{0.4}C_{0.5}F_{0.1} in a nearly pure state. The film had a thickness of 0.100 μm.

### Example 6

### a-SiOC (source is PDMS+CO₂)

The method was carried out as described in Example 1 with 50 sccm CO₂ gas added to the stream of the PDMS vapor. The total flow of PDMS and CO₂ was adjusted to keep a pressure of 0.40 Torr inside the deposition chamber. The duration of deposition was 15 minutes and the temperature of the substrate was 300° C.

After removal from the deposition chamber, the silicon wafer was found to be coated with an amorphous silicon oxycarbide film having the formula Si_{0.45}O_{0.4}C_{0.15} in a nearly pure state. The film had a thickness of 0.250 μm.

Tables 2 and 3 summarize deposition conditions and film compositions of Examples 1-6.

TABLE 2
Deposition conditions of exemplary films.

| | | | Substrate | | | | PDMS | | |
|---|---|---|---|---|---|---|---|---|---|
| | | Time | Temp | Pressure | Thickness | Reactant Gas | Vapor | | Power |
| | Film | (Min) | (° C.) | (Torr) | (nm) | (sccm) | (sccm) | Ar | (watts) |
| Example 1 | a-SiC/Si | 4 | 300 | 0.22 | 100 | — | 30 | 750 | 600 |
| Example 2 | a-SiC/Plastic | 20 | 75 | 0.40 | 200 | — | 20 | 750 | 750 |
| Example 3 | a-SiCN/Si | 15 | 300 | 0.38 | 280 | 500 N₂ | 30 | 500 | 750 |
| Example 4 | a-SiCN/Si | 15 | 300 | 0.40 | 165 | 500 NH₃ | 25 | 500 | 750 |
| Example 5 | a-SiCF/Si | 10 | 300 | 0.44 | 100 | 100 CF₄ | 25 | 800 | 750 |
| Example 6 | a-SiOC/Si | 15 | 300 | 0.40 | 250 | 50 CO₂ | 25 | 750 | 750 |

TABLE 3
Composition of exemplary films as measurements by
X-ray Photoelectron Spectroscopy (XPS).

| | | Film composition | | | | |
|---|---|---|---|---|---|---|
| | | measured by XPS | | | | |
| | | (at. %) | | | | |
| | | Si | C | N | F | O |
| Example 1 | a-SiC/Si | 50 | 49 | 0 | 0 | 1 |
| Example 2 | a-SiC/Plastic | 50 | 48 | 0 | 0 | 2 |
| Example 3 | a-SiCN/Si | 40 | 30 | 30 | 0 | 0 |
| Example 4 | a-SiCN/Si | 47 | 3 | 50 | 0 | 0 |
| Example 5 | a-SiCF/Si | 40 | 50 | 0 | 8 | 2 |
| Example 6 | a-SiOC/Si | 45 | 15 | 0 | 0 | 40 |

### Example 7

### Passivation and Anti-Reflective Properties of Films

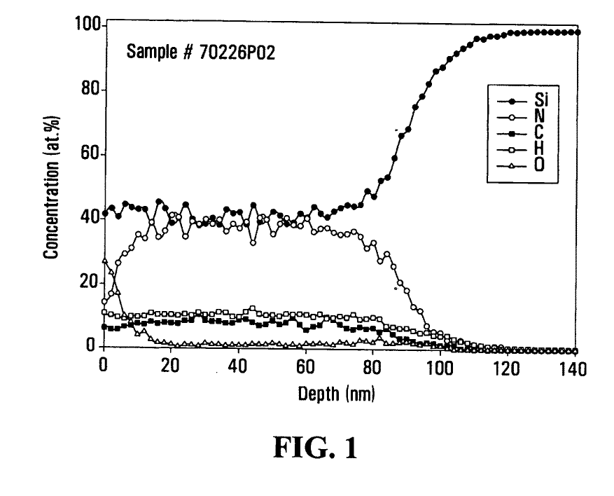

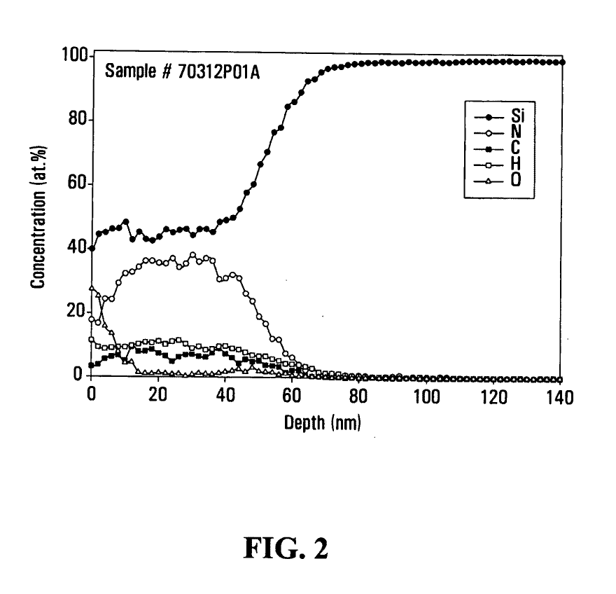

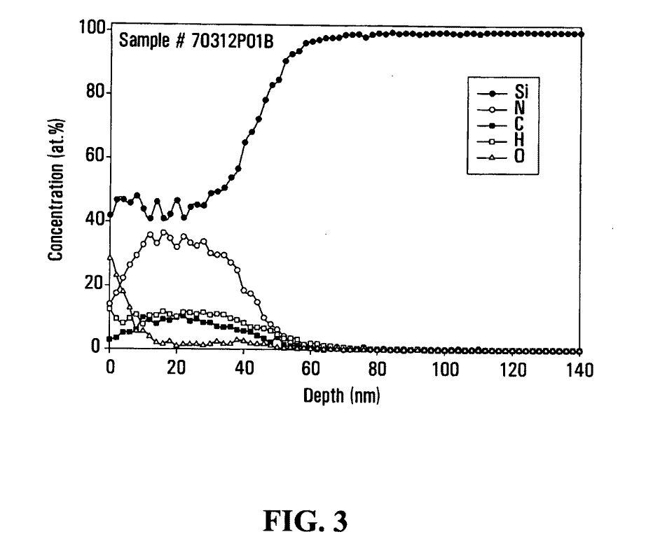

Exemplary films have been deposited onto FZ Si(100) wafers according to the method described herein using the deposition conditions set out in Table 4 to study their passivation and anti-reflective properties. The composition of the exemplary films in Table 4 were determined by XPS (Table 5) and Elastic Recoil Detection (ERD) (FIGS. 1-3).

TABLE 4
Deposition conditions used to prepare exemplary films.

| Sample Name | 70208P02 | 70226P01 | 70226P02 | 70312P01A |
|---|---|---|---|---|
| Coated films | a-SiCN | a-SiCN | a-SiCN | a-SiCN |
| Lifetime (μs) | 1121.7 to | 1488.7 | 1962.2 | 843.52 |
| | 1657.5 | | | |
| Substrate type | FZ Si (100) | FZ Si (100) | FZ Si (100) | FZ Si (100) |
| Resistivity | 3.5-10 | 3.5-10 | 3.5-10 | 3.5-10 |
| (KΩ) | | | | |
| Temperature | 400 | 400 | 400 | 400 |
| ° C. | | | | |
| PDMS flow | 35 | 35 | 35 | 35 |
| (sccm) | | | | |
| Argon (sccm) | 100 | 100 | 100 | 100 |
| NH3 flow | 75 | 250 | 250 | 250 |
| (sccm) | | | | |
| Reactor power | 900 | 900 | 900 | 900 |
| (Watt) | | | | |
| Chamber | 258 | 335 | 330 | 298 |
| pressure | | | | |
| (mTorr) | | | | |

TABLE 5
XPS structural analysis of exemplary a-SiCN:H films.

| Samples | % at.Si | % at.C | % at.O | % at.N | Lifetime (μs) |
|---|---|---|---|---|---|
| 70208p02 | 48.0 | 14.0 | 3.0 | 35.0 | 1121 |
| 70226p02 | 47.4 | 14.6 | 1.5 | 36.5 | 1962 |
| 70312p01A | 35.3 | 16.5 | 8.5 | 39.7 | 844 |
| 70312p01B | 47.5 | 16.4 | 1.6 | 34.5 | 422 |

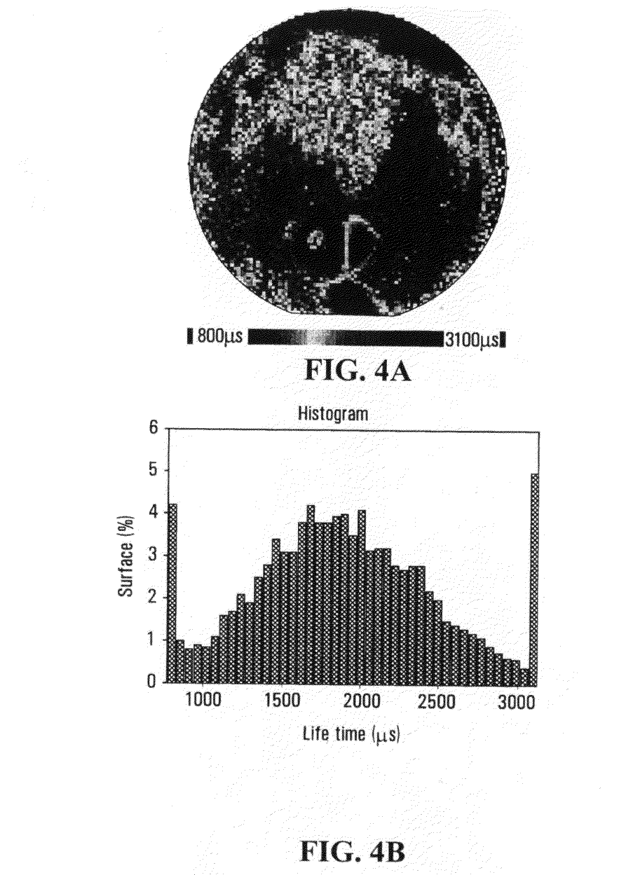

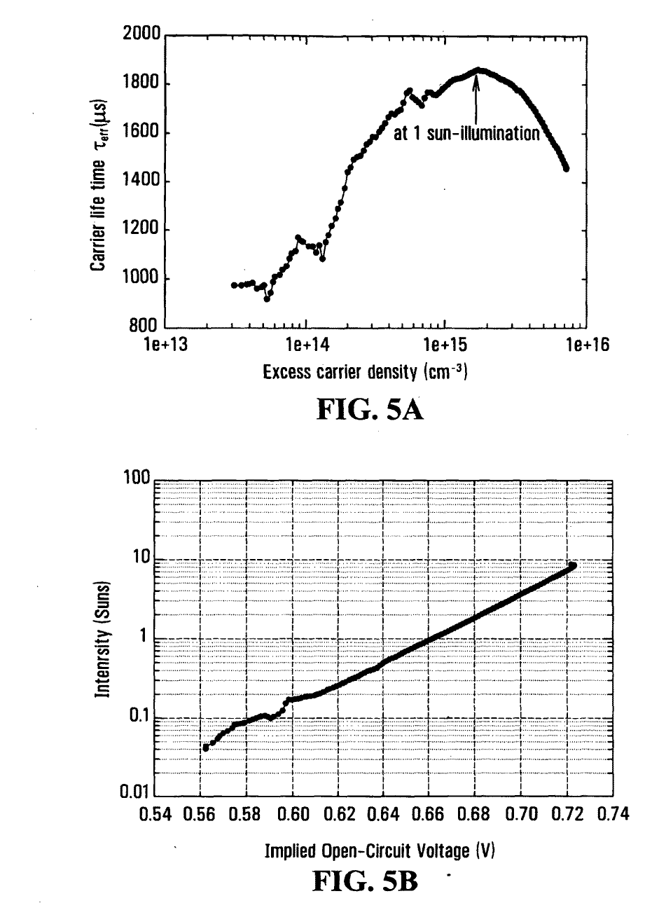

Two techniques were used to evaluate the effective lifetime of the minority carriers in the exemplary films: (1) microwave photoconductive decay (μ-PCD) developed by SEMILAB Semiconductor Physics Laboratory, Inc., and (2) Quasi-Steady-State photo conductance (QSSPC) using a WCT-120 instrument developed by Sinton Consulting, Inc. The results of the two techniques were found to be comparable within ±5% by measuring a sample with each technique (FIGS. 4, 5(a) and 5(b)).

Lifetimes of up to 2500 μs on SiCN:H passivated 4″ FZ Si (100) wafers were measured using the QSSPC method (FIG. 4). Lifetimes of the passivating films produced by the method described herein are unexpectedly better than those found in the art (see Table 6).

TABLE 6

| | | | | Effective | |
|---|---|---|---|---|---|
| Passivation | Substrate | Resistivity | S_{eff} | life time | |
| films | FZ Si | Ω · cm | cm · s⁻¹ | (μs) | Ref. |
| PE-CVD a-SiC | N | 1.5 | 100 | | 12 |
| PE-CVD a-SiCN | N | 1.5 | 2-3 | | |
| PE-CVD a-SiC | | 1.4-1.6 | 54 | 100 | 13 |
| PE-CVD a-SiCN | | | 16 | 1000 | |
| PE-CVD a-SiC | N | 0.85 | ≦100 | | 14 |
| Native oxide | N | 1 | | 130 | 15 |
| | | 1 | | 10-20 | |
| | | 50 | | 2020 | |
| | | 50 | | 215 | |
| | | 50 | | 470 | |
| | | 50 | | 195 | |
| PE-CVD a-SiC | P | 3.3 | 30 | 585 | 16 |
| | | 0.4 | 2400 | 8 | |
| | | 0.4 | 650 | 33 | |
| PE-CVD a-SiC | P | 1 | 1300 | <5 | 17 |
| PE-CVD a-SiC | P | 3.3 | 29 | — | 18 |
| | N | 1.4 | 50 | — | |
| PE-CVD a-SiC | P | 3-4 | 30 | — | 19 |
| PE-CVD a-SiC(n) | | | 10 | — | |
| PE-CVD a-SiC(n) | P | 1 | | 953 | 20 |
| PE-CVD a-SiC | | | | 1356 | 21 |

From the above results, it can be seen that addition of NH₃ in the gas flow leads to an increase in the measured lifetime for the a-SiC:H passivated 4″ FZ Si (100) wafers, demonstrating that the passivation effect can be varied by the presence of nitrogen and/or hydrogen atoms (i.e. the saturation of free bonds).

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

The citation of any publication, patent or patent application in this specification is not an admission that the publication, patent or patent application is prior art.

It must be noted that as used in the specification and the appended claims, the singular forms of “a”, “an” and “the” include plural reference unless the context clearly indicates otherwise.

Unless defined otherwise all technical and scientific terms used herein have the same meaning as commonly understood to one of ordinary skill in the art to which this invention belongs.

### REFERENCES

1. Yao, U.S. Pat. No. 5,800,878.
2. Gardiner et al., U.S. Pat. No. 5,820,664.
3. Chayka, U.S. Pat. No. 5,952,046.
4. M. W. Pitcher et al., Advanced Mater., 16(8), 706 (2004).
5. Goldstein, U.S. Pat. No. 5,850,064 and Shen et al., U.S. Pat. No. 6,730,802.
6. Goela et al., U.S. Pat. No. 5,612,132.
7. Moehle et al., U.S. Pat. No. 5,209,979.
8. Ruppel et al., U.S. Pat. No. 5,944,963.
9. M. S. Aida and M. Ghrieb, Mater. Chem. and Phys., 47(1), 97-100 (1997).
10. R. Riedel, A Kienzle, W. Dressler, L. Ruwisch, J. Bill, and F. Aldinger, Nature, 382, 796 (1996).
11. P. A. Ramakrishnan, Y. T. Wang, D. Balzar, Linan An, C. Haluschka and R. Riedel, and A. M. Hermann, Appl. Phys. Lett., 78(20), 3076 (2001).
12. M. Vetter, I. Martin, A. Orpella, J. Puigdollers, C. Voz, R. Alcubilla, Thin solid Films, 451-452 (2004) pp. 340-344.
13.1. Martin, M. Vetter, A. Orpella, G. Voz, J. Puigdollers, and R. Alcubilla, Appl. Phys. Lett. 81 (23) (2002) 4461-4463.
14. M. Vetter, C. Voz, R. Ferre, I. Martin, A. Orpella, J. Puigdollers, J. Andreu, and R. Alcubilla, Thin Solid Films, 511-512 (2006) 290-294.
15. A. Cuevas, Solar energy Mater. Sol. Cells, 71 (2002) pp. 295-312.
16.1. Martin, M. Vetter, A. Orpella, and J. Puigdollers, A. Cuevas, R. Alcubilla, Appl. Phys. Lett., 79 (14), (2001) pp. 2199-2201.
17. S. W. Glunz, Presented at the 4^{th} World Conference on Photovoltaic Energy Conversion, Hawaii, May 2006.
18.1. Martin, M. Vetter, M. Garín, A. Orpella, C. Voz, J. Puigdollers, and R. Alcubilla J. Appl. Phys., 98 (2005) pp. 114912.
19. M. Vetter, I. Martin, A. Orpella, C. Voz, J. Puigdollers and R. AlcubillaMat. Res. Soc. Symp. Proc., 715 (2002) pp. A24.5.1.
20. S. Janz, S. Riepe, M. Hofmann, S. Reber, and S. Glunz, Appl. Phys. Lett., 88 (2006) pp. 133516.
21. S. W. Glunz, S. Janz, M. Hofmann, T. Roth, and G. Willeke, Paper presented at the 4^{th} World Conference on Photovoltaic Energy Conversion, Hawaii, May, 2006.

1. A method for forming a film on a substrate comprising:
heating a solid organosilane source in a heating chamber to form a gaseous precursor;
transferring the gaseous precursor to a deposition chamber containing the substrate; and
reacting the gaseous precursor using an energy source to form the film on the substrate.

2. The method according to claim 1, wherein the energy source is electrical heating, UV irradiation, IR irradiation, microwave irradiation, X-ray irradiation, electron beam, RF, or plasma.

3. The method according to claim 1, wherein the energy source is plasma.

4. The method according to claim 3, wherein the film is formed on the substrate by plasma enhanced chemical vapor deposition (PECVD), radio frequency plasma enhanced chemical vapor deposition (RF-PECVD), electron-cyclotron-resonance plasma-enhanced chemical-vapor deposition (ECR-PECVD), inductively coupled plasma-enhanced chemical-vapor deposition (ICP-ECVD), plasma beam source plasma enhanced chemical vapor deposition (PBS-PECVD), or combinations thereof.

5. The method according to claim 1, wherein the heating chamber is heated to a temperature in the range of from 50 to 700° C.

6. The method according to claim 1, wherein the heating chamber is heated to a temperature in the range of from 475 to 500° C.

7. The method according to claim 1, wherein the substrate is at a temperature in the range of from 25 to 500° C.

8. The method according to claim 1, wherein the gaseous precursor is transferred to the deposition chamber in a continuous flow.

9. The method according to claim 1, wherein the gaseous precursor is transferred to the deposition chamber in a pulsed flow.

10. The method according to claim 1, wherein the deposition chamber is within a reactor and the heating chamber is external to the reactor.

11. The method according to claim 1, wherein the deposition chamber and the heating chamber are both within a reactor.

12. The method according to claim 1, wherein the solid organosilane source is a silicon-based polymer.

13. The method according to claim 12, wherein the silicon-based polymer comprises Si—C bonds which are thermodynamically stable during heating in the heating chamber.

14. The method according to claim 12, wherein the silicon-based polymer has a monomeric unit comprising at least one silicon atom and two or more carbon atoms.

15. The method according to claim 14, wherein the monomeric unit further comprises N, O, F, B, P or a combination thereof.

16. The method according to claim 1, wherein the solid organosilane source is polydimethylsilane, polycarbomethylsilane, triphenylsilane, or nonamethyltrisilazane.

17. The method according to claim 1, wherein the solid organosilane source comprises a synthetic ratio of isotope.

18. The method according to claim 1, wherein the film comprises silicon carbide (SiC), silicon carbofluoride (SiCF), silicon carbonitride (SiCN), silicon oxycarbide (SiOC), silicon oxycarbonitride (SiOCN), silicon carboboride (SiCB), silicon carbonitroboride (SiCNB), silicon carbophosphide (SiCP), or a combination thereof.

19. The method according to claim 1 further comprising mixing the gaseous precursor with a reactant gas prior to the reacting step.

20. The method according to claim 19, wherein the reactant gas is CF₄, C₄F₈, CH₂F₂, NF₃, C₂F₆, C₃F₈, CHF₃, C₂F₄, C₃F₆, or a combination thereof.

21. The method according to claim 19, wherein the reactant gas is N₂, NH₃, or NCl₃.

22. The method according to claim 19, wherein the reactant gas is O₂, O₃, CO, or CO₂.

23. The method according to claim 19, wherein the reactant gas is BH₃, BCl₃, B₂H₆, or B₂Cl₆.

24. The method according to claim 19, wherein the reactant gas is PH₃ or PCl₃.

25. The method according to claim 19, wherein the reactant gas is formed by heating difluorobenzene.

26. The method according to claim 19, wherein the reactant gas is formed by heating triphenylphosphine, triethylphosphine, dimethylphenylphosphine, or tris(trimethylsilyl)phosphine.

27. The method according to claim 19, wherein the reactant gas is formed by heating tris(pyrazol-1-yl)methane.

28. The method according to claim 19, wherein the reactant gas is formed by heating borane t-butylamine, triethanolamineborate, borane dimethylamine, or tris(trimethylsiloxy)boron.

29. The method according to claim 1, wherein the transferring step comprises using a carrier gas.

30. The method according to claim 29, wherein the carrier gas is He, Ar, Ne, or a combination thereof.

31. A film obtained from the method as claimed in claim 1 or claim 37.

32. A method for surface passivation of a silicon based semiconductor, comprising depositing a film on the surface of the semiconductor according to the method of claim 1 or claim 37.

33. The method according to claim 32, wherein the film comprises silicon carbide (SiC), silicon carbofluoride (SiCF), silicon carbonitride (SiCN), silicon oxycarbide (SiOC), silicon oxycarbonitride (SiOCN), silicon carboboride (SiCB), silicon carbonitroboride (SiCNB), silicon carbophosphide (SiCP), or a combination thereof.

34. The method according to claim 32, which comprises a further step of annealing the semiconductor after deposition.

35. The method according to claim 34, wherein the annealing is rapid thermal annealing, hot-gas annealing, belt furnace annealing or isothermal annealing.

36. A container comprising a gaseous precursor produced by heating a solid organosilane source, for use in the method as claimed in claim 1 or claim 37.

37. A method for forming a film on a substrate comprising:
heating a solid silicon-based polymer in a heating chamber to form a gaseous precursor, wherein the heating chamber is heated to a temperature in the range of from 50 to 700° C.;
transferring the gaseous precursor to a deposition chamber containing the substrate; and
reacting the gaseous precursor using electrical heating, UV irradiation, IR irradiation, microwave irradiation, X-ray irradiation, electron beam, RF, or plasma to form the film on the substrate.
